(19) United States
(12) Patent Application Publication
(10) Pub. No.: US 2015/0263013 A1
(43) Pub. Date: Sep. 17, 2015

(54) NON-VOLATILE SEMICONDUCTOR MEMORY DEVICE

(71) Applicant: KABUSHIKI KAISHA TOSHIBA, Tokyo (JP)

(72) Inventors: Takashi FURUHASHI, Yokkaichi Mie (JP); Atsushi MURAKOSHI, Yokkaichi Mie (JP); Kenichiro TORATANI, Yokkaichi Mie (JP); Masayuki TANAKA, Yokkaichi Mie (JP); Yoshio OZAWA, Yokkaichi Mie (JP)

(21) Appl. No.: 14/617,328

(22) Filed: Feb. 9, 2015

Related U.S. Application Data
(60) Provisional application No. 61/951,738, filed on Mar. 12, 2014.

(51) Int. Cl. H01L 27/115; H01L 29/423; H01L 29/788; H01L 29/51

(52) U.S. Cl. CPC H01L 27/11521; H01L 29/513; H01L 29/518; H01L 29/42324; H01L 29/7883

(57) ABSTRACT

A non-volatile semiconductor memory device according to an embodiment includes a semiconductor substrate, a tunnel insulating film on the semiconductor substrate, a first electric charge storage layer on the tunnel insulating film, a first insulating layer on the first electric charge storage layer, a second electric charge storage layer on the first insulating layer and including a metal containing layer, a first metal diffusion suppressing layer on the second electric charge storage layer to suppress diffusion of metal contained in the second electric charge storage layer, a second insulating layer on the first metal diffusion suppressing layer, and a control electrode on the second insulating layer.

### CROSS-REFERENCE TO RELATED APPLICATION

This application is based upon and claims the benefit of priority from U.S. Provisional Patent Application No. 61/951,738, filed Mar. 12, 2014, the entire contents of which are incorporated herein by reference.

### BACKGROUND

A large capacity non-volatile semiconductor memory device includes plural memory cells and stores data in the memory cells. The memory cell has a structure that includes a tunnel insulating film formed on a semiconductor substrate, an electric charge storage layer formed on the tunnel insulating film, an insulating layer formed on the electric charge storage layer, and a control electrode formed on the insulating layer in many cases. Here, when a metal element is added to the electric charge storage layer, the metal element is possibly diffused to the outside (outward-diffusion) from the electric charge storage layer. As a result, the data storing property of the memory cell may be deteriorated.

### BRIEF DESCRIPTION OF THE DRAWINGS

FIG. 1A is a diagram illustrating a memory cell area of a non-volatile semiconductor memory apparatus according to the embodiments.

FIG. 1B is a plan view illustrating memory cells in the memory cell area of the non-volatile semiconductor memory apparatus according to the embodiments.

FIG. 2A is a longitudinal cross-sectional view of a first embodiment taken along line 2A-2A of FIG. 1B.

FIG. 2B is a longitudinal cross-sectional view of the first embodiment taken along line 2B-2B of FIG. 1B.

FIG. 2C is a timing chart illustrating timings of applying voltages during reading according to the embodiments.

FIGS. 3 to 11 are longitudinal cross-sectional views of the first embodiment, illustrating steps in a manufacturing method of a portion of memory cells taken along line 2B-2B of FIG. 1B.

FIG. 12 is a longitudinal cross-sectional view of the first embodiment, illustrating a step in a manufacturing method of the portion of memory cells taken along line 2A-2A of FIG. 1B.

FIG. 13A is a longitudinal cross-sectional view of a second embodiment taken along line 2A-2A of FIG. 1B.

FIG. 13B is a longitudinal cross-sectional view of the second embodiment taken along line 2B-2B of FIG. 1B.

FIG. 13C is a plan view of the second embodiment taken along lines A-A of FIGS. 13A and 13B illustrating a partial structure in the memory cell area.

FIGS. 14 to 25 are longitudinal cross-sectional views of the second embodiment, illustrating steps in a manufacturing method of a portion of memory cells taken along line 2B-2B of FIG. 1B.

FIG. 26 is a longitudinal cross-sectional view of the second embodiment, illustrating a step in a manufacturing method of the portion taken along line 2A-2A of FIG. 1B.

### DESCRIPTION

A non-volatile semiconductor memory device according to the embodiments includes: a semiconductor substrate, a tunnel insulating film on the semiconductor substrate, a first electric charge storage layer on the tunnel insulating film, a first insulating layer on the first electric charge storage layer, a second electric charge storage layer on the first insulating layer and including a metal containing layer, a first metal diffusion suppressing layer on the second electric charge storage layer to suppress diffusion of the metal contained in the second electric charge storage layer, a second insulating layer on the first metal diffusion suppressing layer, and a control electrode on the second insulating layer.

Hereinafter, embodiments of a non-volatile semiconductor memory apparatus and a manufacturing method thereof are described with reference to the drawings. Further, with respect to the description in the drawings referred hereto, the same or similar portions are indicated by providing the same or similar reference numerals. The drawings are schematically provided, and the relation between the thickness and the flat dimension, the ratios of the thicknesses of the respective layers, and the like are not necessarily equal to actual thicknesses. In addition, upper, lower, left, and right directions indicate relative directions when a circuit formed surface side of a semiconductor substrate described below is faced up, and do not correspond to directions based on the gravitational acceleration direction. In addition, for convenience of the description, upper, lower, left, and right directions, or high and low directions, or a depth direction of a groove, or the like according to the descriptions of the embodiments are relative positional relations based on a rear surface side of the semiconductor substrate described below.

Furthermore, herein below, an XYZ rectangular coordinate system is used for convenience of the description. With respect to the coordinate system, two directions parallel to the surface of the semiconductor substrate and intersecting each other are set to be X and Y directions, and the direction intersecting the X and Y directions is set to be a Z direction.

### First Embodiment

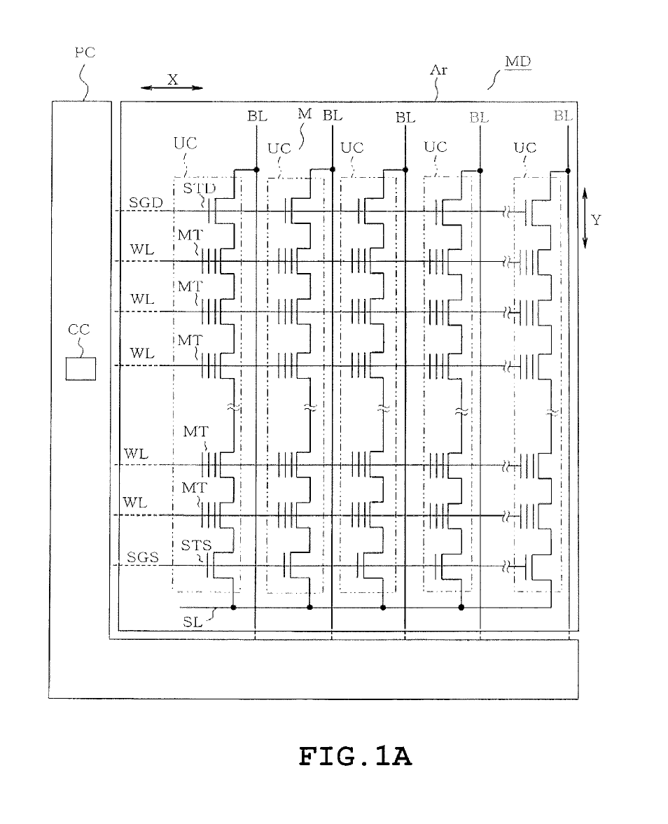

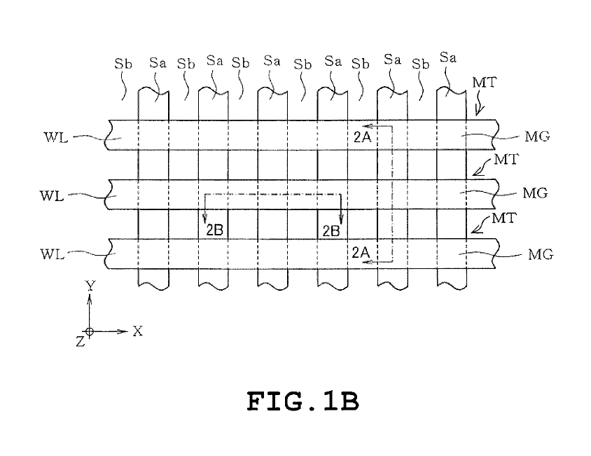

FIG. 1A is a diagram illustrating an electric configuration of a planar-type NAND-type flash memory apparatus. FIG. 1B is a plan view schematically illustrating a portion of a memory cell area.

Referring to FIG. 1A, A NAND-type flash memory apparatus MD is a non-volatile semiconductor memory apparatus that includes a memory cell array Ar that has a plurality of cell units UC arranged in a matrix in a memory cell area M. Also shown are a control circuit CC that drives the memory cell array Ar, and a peripheral circuit PC. The plurality of cell units UC are provided parallel to each other along the X direction of the memory cell area M. In FIG. 1A, only one block is illustrated in FIG. 1A for convenience of the description. In the actual apparatus, additional cell unit groups, each having a plurality of cell units UC and corresponding to the one block, are arranged in the Y direction.

Each of the cell units UC has two selection transistors, STD and STS, and a plurality (for example, 64) of memory cells MT. The plurality of memory cells MT are connected in series between the selection transistors STD and STS. The plurality of memory cells MT form a cell string. One side of a drain and a source of the selection transistor STD is connected to bit lines BL, and the other side is connected to one side of a drain and a source of a memory cell MT disposed in an end portion of the cell string. The other side of the cell string is connected to one side of a drain and a source of the selection transistor STS, and the other side of the drain or source of the selection transistor STS is connected to source lines SL.

In addition, as illustrated in FIG. 1B, element areas Sa of the memory cells MT are formed in the Y direction to be separated from each other in the X direction. These element areas Sa are segmented by element separation areas Sb. In addition, the memory cells MT of the different cell units UC are commonly connected to each other in the X direction by word lines WL.

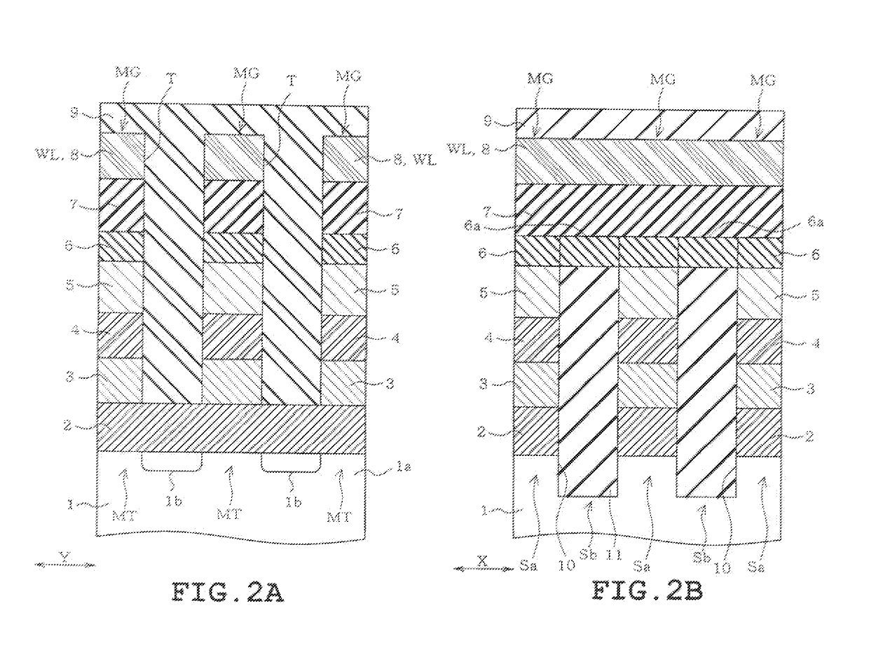

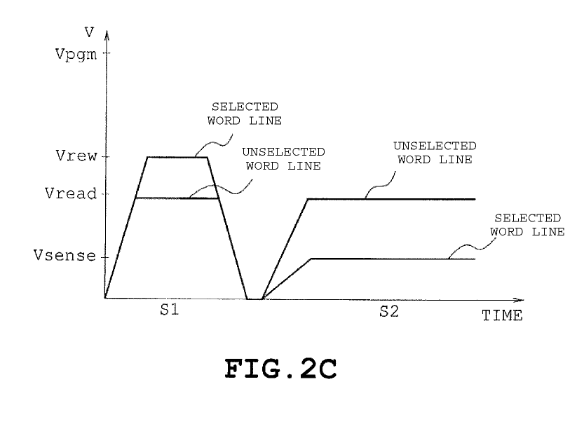

FIG. 2A is a cross-sectional view taken along line 2A-2A of FIG. 1B in the channel length or bit line direction, schematically illustrating a structure of a planar-type NAND cell string. FIG. 2B is a cross-sectional view taken along line 2B-2B of FIG. 1B in the channel width or word line direction, schematically illustrating a sectional structure of the NAND cell string.

In the schematic cross-sectional view illustrated in FIG. 2A, a plurality of the memory cells MT in a cell string along line 2A of FIG. 1B are arranged parallel to each other on a semiconductor substrate 1. A p-type silicon single crystal substrate can be used for the substrate 1. The plurality of memory cells MT each include a gate electrode (hereinafter, referred to as a gate) MG formed over a semiconductor channel 1a of the semiconductor substrate 1. Source or drain areas 1b are formed on a surface layer of the semiconductor substrate 1 on both sides of the gate MG. The gates MG in FIG. 2A are separated from each other by grooves T formed along a depth direction (X direction) of the printed surface of FIG. 2A.

The gate MG is formed by sequentially stacking a first electric charge storage layer 3, a first insulating layer 4, a second electric charge storage layer 5, a first metal diffusion suppressing layer 6, a second insulating layer 7, and a control electrode 8 on the tunnel insulating film 2. The tunnel insulating film. 2 can be formed of a silicon oxide film. The tunnel insulating film 2 allows an FN tunneling current to flow and is formed to have a certain film thickness of 3 nm or greater.

The first electric charge storage layer 3 is formed to be in contact with the upper surface of the tunnel insulating film 2. The first electric charge storage layer 3 can be formed of polysilicon, for example a p-doped polysilicon, such as polysilicon layer doped with boron. The first electric charge storage layer 3 is formed to have a film thickness equal to or less than the film thickness of the tunnel insulating film 2.

The first insulating layer 4 is formed to be in contact with the upper surface of the first electric charge storage layer 3. The first insulating layer 4 is formed of, for example, a silicon nitride film, an Oxide-Nitride-Oxide (ONO) film, a Nitride-Oxide-Nitride-Oxide-Nitride (NONON) film, or a stacked film in which the nitride film between the ONO film or the NONON film is replaced with a high-permittivity insulating film (High-K film: for example, alumina or hafnia). The first insulating layer 4 can also function as a charge trapping film. The first insulating layer 4 is formed to have a film thickness equal to or less than the film thickness of the tunnel insulating film 2.

The second electric charge storage layer 5 is formed to be in contact with the upper surface of the first insulating layer 4, and formed of, for example, a conductive metal layer or a metal-containing layer. The second electric charge storage layer 5 is formed to have a film thickness equal to or less than the tunnel insulating film 2. The metal contained in the second electric charge storage layer 5 can contain at least one of ruthenium (Ru), tungsten (W), tungsten silicide (WSi), chromium (Cr), copper (Cu), and the like. In some embodiments, the second electric charge storage layer 5 only includes one of the metals or metallic compounds described above.

The first metal diffusion suppressing layer 6 is formed to be in contact with the upper surface of the second electric charge storage layer 5 and is provided for the purpose of suppressing the diffusion of the metal contained in the second electric charge storage layer 5. The first metal diffusion suppressing layer 6 may be formed of a silicon nitride (SiN) film or a stacked layer film including the silicon nitride film. Boron (B) and/or carbon (C), or the like can be included in the silicon nitride film of the first metal diffusion suppressing layer 6 in some embodiments. The first metal diffusion suppressing layer 6 is formed to have a film thickness equal to or less than the film thickness of the tunnel insulating film 2.

The second insulating layer 7 is formed to be in contact with the upper surface of the first metal diffusion suppressing layer 6. The second insulating layer 7 can be a high-permittivity insulating film (High-K film: for example, alumina, or hafnia). The second insulating layer 7 can be formed with a stacked layer film of a high-permittivity insulating film and a silicon oxide film. The second insulating layer 7 includes a charge blocking film that suppresses the passage of charges. The second insulating layer 7 is formed to have a film thickness of equal to or greater than the film thickness of the tunnel insulating film 2.

The control electrode 8 is formed to be in contact with the upper surface of the second insulating layer 7. The control electrode 8 can be formed of n-doped or p-doped polysilicon, a stack of doped polysilicon with a metal film formed on the polysilicon, a stack of doped polysilicon with a silicide layer obtained by performing a silicide process on a metal formed on the polysilicon, and the like.

An interlayer insulating film 9 is formed to cover the plurality of gates MG. The interlayer insulating film 9 can be formed of a silicon oxide film. The interlayer insulating film 9 may be formed only on the upper surface of the control electrode 8, and accordingly gaps may be provided between the adjacent gates MG-MG. In the present embodiment, the gaps are not provided.

As illustrated in FIG. 2B, the gate MG is formed on the semiconductor channel 1a of the semiconductor substrate 1 over the tunnel insulating film 2 by stacking the first electric charge storage layer 3, the first insulating layer 4, the second electric charge storage layer 5, the first metal diffusion suppressing layer 6, the second insulating layer 7, and the control electrode 8 in this sequence.

Element separation grooves 10 are formed on the semiconductor substrate 1. The element separation grooves 10 are formed to separate the element areas Sa, the tunnel insulating films 2, the first electric charge storage layers 3, the first insulating layers 4, and the second electric charge storage layers 5 in the X direction. Element separation films 11 are embedded in the element separation grooves 10. The element separation films 11 are formed with, for example, silicon oxide films, and are formed to protrude more upwardly than the upper surface of the semiconductor substrate 1. The element separation films 11 are formed in Shallow Trench Isolation (STI) structures.

In the schematic cross-sectional view illustrated in FIG. 2B, the first metal diffusion suppressing layer 6, the second insulating layer 7, and the control electrode 8 are sequentially formed on the upper surface of the second electric charge storage layer 5. A film 6a, the second insulating layer 7, and the control electrode 8 are sequentially formed on the upper surface of the element separation film 11. The film 6a may be configured with the same material as the first metal diffusion suppressing layer 6. As a result, the film 6a has a metal diffusion suppressing function. Alternatively, the material of the film 6a may be different from the material of the first metal diffusion suppressing layer 6. Here, even if the material of the film 6a is different from the material of the first metal diffusion suppressing layer 6, the film 6a still has the metal diffusion suppressing function in some embodiments. The film thicknesses of the film 6a and the first metal diffusion suppressing layer 6 in the stacked direction (Z direction) can be almost the same. Here, the upper surface of the second electric charge storage layer 5 and the upper surface of the element separation film 11 are at almost the same height in the Z direction. In addition, the first metal diffusion suppressing layer 6 and the film 6a continuously cover the upper surfaces of the second electric charge storage layer 5 and the element separation films 11 in the X direction. As a result, the diffusion of the metal element from the second electric charge storage layer 5 to the second insulating layer 7 may be prevented. Here, the second insulating layer 7 and the control electrode 8 are continuously formed in the X direction. The interlayer insulating film 9 is formed on the upper surface of the control electrode 8.

According to the structure of the present embodiment, the first electric charge storage layer 3, the first insulating layer 4, and the second electric charge storage layer 5 are stacked on the semiconductor substrate 1 over the tunnel insulating film 2. Therefore, it is possible to effectively store charges by using the multi-stage electric charge storage layers 3 and 5. In addition, since the first metal diffusion suppressing layer 6 is formed on the second electric charge storage layer 5, it is possible to suppress the diffusion of the metal contained in the second electric charge storage layer 5. As a result, it is possible to enhance an ability of accumulating charges in the second electric charge storage layer 5 so that a data storing property may be enhanced.

In addition, if the second insulating layer 7 includes a portion to trap charges, the diffusion of the metal contained in the second electric charge storage layer 5 to the second insulating layer 7 may be further suppressed enabling the charges to be effectively and efficiently stored in the second electric charge storage layer 5. Consequently, writing speed and deleting speed may be further enhanced.

The data storing property may be enhanced by the operation as illustrated in FIG. 2C. Referring to FIGS. 1A-2C, a writing operation and a reading operation are described. The writing process and the reading process are performed by the control circuit CC in the peripheral circuit PC. Initially, the memory cells MT to be the writing target or the reading target are selected. Then the control circuit CC may apply predetermined voltages to the bit lines BL and word lines WL of the selected memory cells MT and the unselected memory cells MT.

The control circuit CC may perform the data writing process to the selected memory cells MT by applying a program voltage Vpgm (writing voltage: high voltage) to the selected word lines WL (the control electrode 8) and applying a low voltage (<Vpgm) to the bit lines BL on the semiconductor substrate 1. Then, the FN tunneling current flows through the tunnel insulating film 2 and charges are injected from the semiconductor substrate 1 to the first and second electric charge storage layers 3, 5 of the memory cells MT selected for writing.

Meanwhile, when the control circuit CC in the peripheral circuit PC performs the reading process, the data reading process from the memory cells MT performs a reading control process as illustrated in FIG. 2C. The control circuit CC applies a sense voltage Vsense to a selected word line, and applies a read voltage Vread to an unselected word line. As a result, data of a memory cell MC connected to the selected word line may be read.

Here, until the reading process of the charges stored in the second electric charge storage layer 5 is performed, some of the stored charges in the second electric charge storage layer 5 may migrate to the first electric charge storage layer 3. Then, the threshold voltage of the memory cells MT that are the read target may be changed according to the change in the amount of charges stored in the first electric charge storage layer 3 of the memory cells MT that are the read target.

Accordingly, in the present embodiment, before the data reading process from the selected memory cell MT, the control circuit CC applies a voltage Vrew that is greater than the read voltage Vread and smaller than the program voltage Vpgm to the control electrode 8 (the selected word line WL) connected to the selected memory cell MT (S1 of FIG. 2C). At this point, a low voltage (<Vrew) may be applied to the semiconductor substrate 1. In addition, the read voltage Vread may be applied to the unselected word line. As a result, charges in the first electric charge storage layer 3 of the selected memory cell MT, that migrated to the first electric charge storage layer 3 from the second electric charge storage layer 5, are returned to the second electric charge storage layer 5 of the selected memory cell MT.

After this, the control circuit CC applies the read voltage Vread to the control electrode 8 (the word line WL) connected to the selected memory cell MT, and also applies the sense voltage Vsense lower than the read voltage Vread, to the bit line BL (S2 of FIG. 2C). Accordingly, even if some of the stored charge of the second electric charge storage layer 5 is migrated to the first electric charge storage layer 3, the data reading process may be correctly performed.

Hereinafter, an example of a method of manufacturing a non-volatile semiconductor memory apparatus according to the present embodiment is described. In the description below, although general portions are described other operations may be added between the respective operations, and some of the following operations may be removed as well, if necessary. In addition, if it is practically possible, the operations may be appropriately replaced.

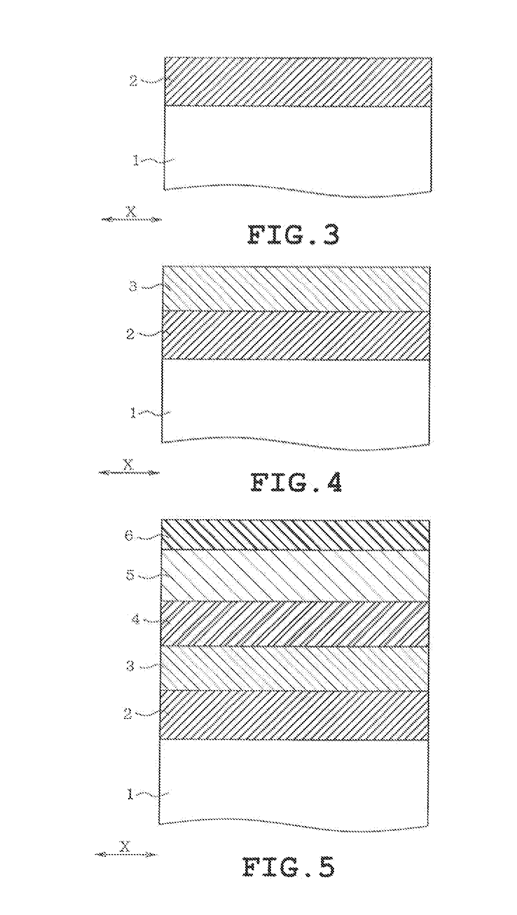

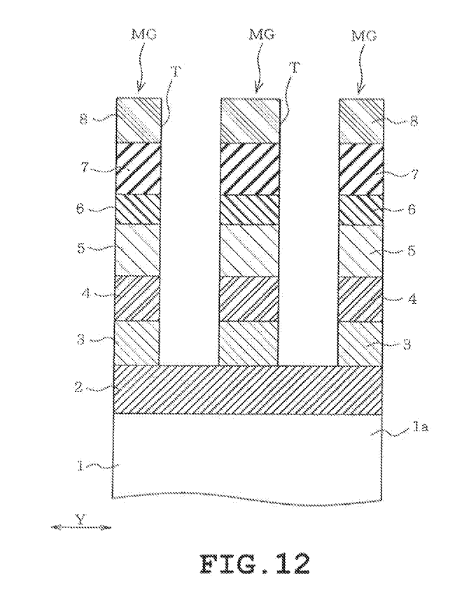

FIGS. 3 to 11 illustrate manufacturing steps of forming the structure shown in FIG. 2B. FIG. 12 illustrates a manufacturing step of forming the structure shown in FIG. 2A after the manufacturing step shown in FIG. 11.

First, as shown in FIG. 3, the tunnel insulating film 2 is formed on the semiconductor substrate 1. For example, if a silicon oxide film is used as the tunnel insulating film 2, the tunnel insulating film 2 may be formed by using a thermal oxidation method.

As illustrated in FIG. 4, the first electric charge storage layer 3 is formed on the tunnel insulating film 2, by, for example, a CVD method. The first electric charge storage layer 3 can be a p-type doped polysilicon layer, which is doped with, for example, boron (B). In any of the described manufacturing methods, the polysilicon to which the dopants are added, the p-type dopants may be introduced to the polysilicon film an ion implantation method. Alternatively, the polysilicon film may be formed while the p-type dopants are being introduced.

As illustrated in FIG. 5, the first insulating layer 4, the second electric charge storage layer 5, and the first metal diffusion suppressing layer 6 are sequentially formed on the first electric charge storage layer 3. The first insulating layer 4 can be formed of, for example, a silicon nitride film. The first insulating layer 4 can be formed by using, for example, a CVD method. The second electric charge storage layer 5 may be formed a metal or metal-containing material. The first metal diffusion suppressing layer 6 can be formed of a silicon nitride film, such as a silicon nitride film containing boron (B). The first metal diffusion suppressing layer 6 may be formed by using, for example, a CVD method.

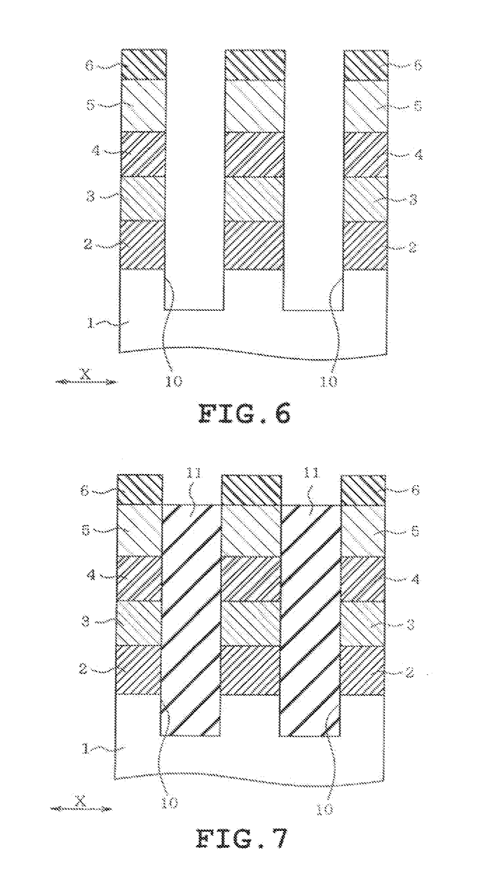

Next, a resist mask (not illustrated) is patterned on the first metal diffusion suppressing layer 6 by a lithography process. A resist mask is used as a mask, and portions of the first metal diffusion suppressing layer 6, the second electric charge storage layer 5, the first insulating layer 4, the first electric charge storage layer 3, the tunnel insulating film 2, and the surface layer of the semiconductor substrate 1 are sequentially etched forming the element separation grooves as illustrated in FIG. 6. The etching can be done by using Reactive Ion Etching (RIE).

The element separation grooves 10 are formed to extend in the depth direction (Y direction) of the printed surface and formed to penetrate the first metal diffusion suppressing layer 6, the second electric charge storage layer 5, the first insulating layer 4, the first electric charge storage layer 3, and the tunnel insulating film 2. In addition, the element separation grooves 10 extend down to lower than the upper surface of the semiconductor substrate 1.

Subsequently, as illustrated in FIG. 7, the element separation films 11 are formed in the element separation grooves 10. The element separation films 11 can be formed with, for example, a silicon oxide film. The element separation films 11 can be formed by using a CVD method and/or a coating method or the like. Generally, embedding the element separation films 11 in the element separation grooves 10 is performed by forming the element separation film 11 to be raised to or above the upper surface of the first metal diffusion suppressing layer 6. Then an etching is performed so that the height of the upper surface of the element separation film 11 becomes the same height of the upper surface of the second electric charge storage layer 5.

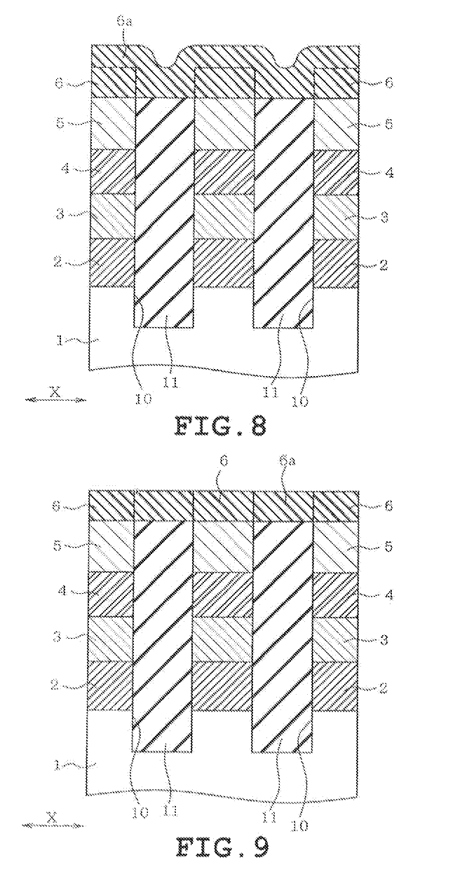

As illustrated in FIG. 8, the film 6a having the same metal as the material of the first metal diffusion suppressing layer 6 is formed along the upper surface of the first metal diffusion suppressing layer 6 and the upper surface of the element separation film 11. The material of the film 6a may be the same or different from the material of the first metal diffusion suppressing layer 6.

As illustrated in FIG. 9, the positions of the upper surfaces of the first metal diffusion suppressing layer 6 and the film 6a are set to be almost the same by performing the process of flattening the film 6a by a CMP method or performing an etchback process with an RIE method according to the anisotropic conditions.

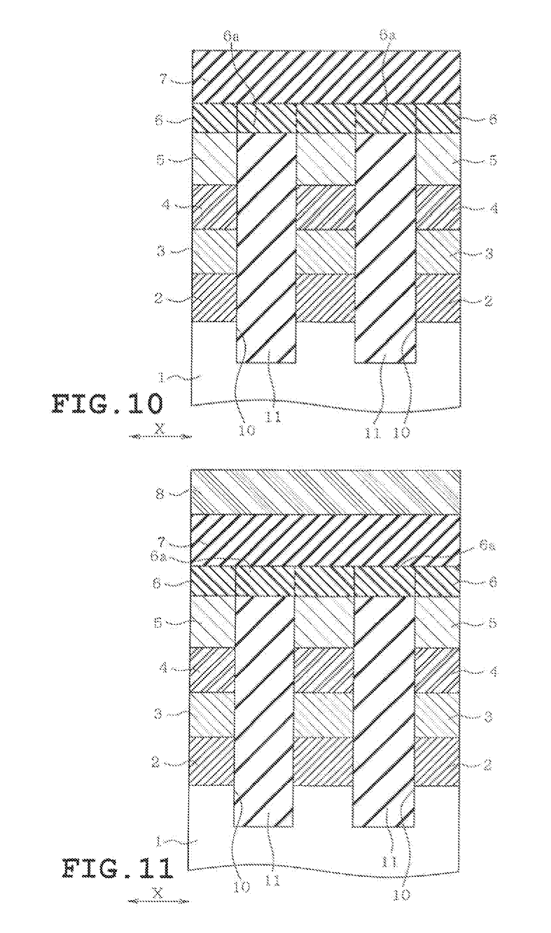

As illustrated in FIG. 10, the second insulating layer 7 is formed on the first metal diffusion suppressing layer 6 and the film 6a. The second insulating layer 7 can be formed of a stacked layer film of a high-permittivity insulating film and a silicon oxide film. Alternatively, the second insulating layer 7 may be a single layer of the high-permittivity insulating film or the silicon oxide film. The second insulating layer 7 can be formed by using an ALD method, a CVD method, or the like.

As illustrated in FIG. 11, the control electrode 8 is formed on the second insulating layer 7. The control electrode 8 can be formed of polysilicon by using a CVD method.

A resist mask (not shown) is patterned on the control electrode 8, and the patterned resist mask is used as a mask, to form grooves T on the stacking structures 3 to 8 as illustrated in FIG. 12. The grooves T are formed to extend along the depth direction (X direction) of the printed surface, and the grooves T segment the stacking structures 3 to 8 by penetrating the control electrode 8, the second insulating layer 7, the first metal diffusion suppressing layer 6, the second electric charge storage layer 5, the first insulating layer 4, and the first electric charge storage layer 3. Accordingly, the gates MG of the separate memory cells are formed. According to the present embodiment, it is described that the tunnel insulating film 2 is formed to continue in the Y direction under the plurality of gates MG, but the grooves T may be formed to segment the tunnel insulating film 2 in the Y direction.

Then, dopants can be doped into the surface layer of the semiconductor substrate 1 by using an ion implantation method. As illustrated in FIGS. 2A and 2B, the dopants form the source or drain areas 1b. The dopants can be added according to the following heat process. The interlayer insulating film 9 is formed on the stacking structures 2 to 8 and element grooves on the semiconductor substrate 1. The interlayer insulating film 9 can be formed with a silicon oxide film. The interlayer insulating film 9 can be formed by a CVD method, such as a plasma CVD method and the like. Thereafter bit line contacts, source line contacts, via plugs, source lines, bit lines, wire lines and other structures are formed, the detailed descriptions of which are not provided. According to the present embodiment, the charge storing property of the memory cell MT may be enhanced.

### Second Embodiment

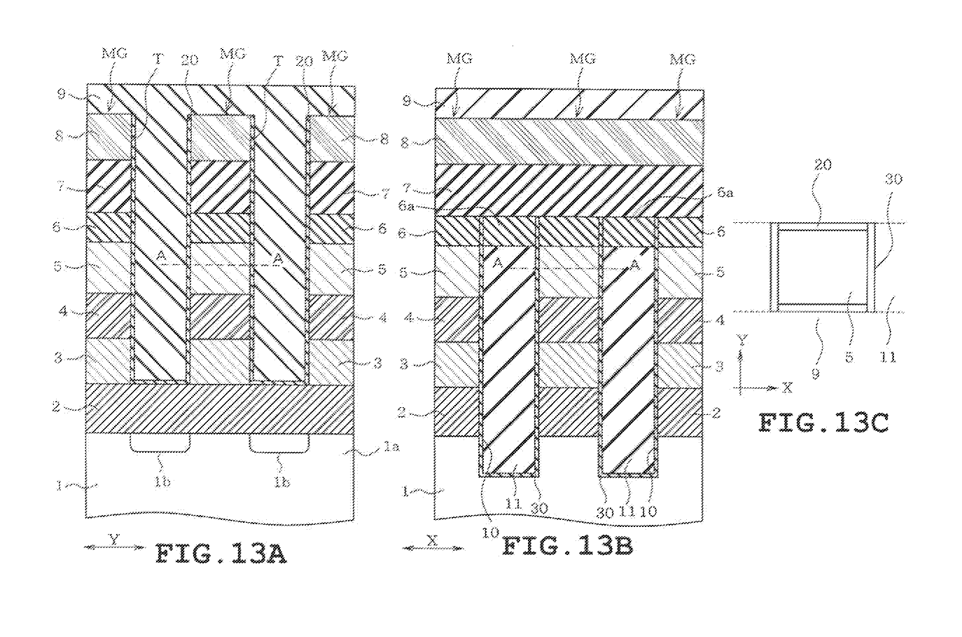

FIGS. 13A to 26B are diagrams illustrating the second embodiment. According to the second embodiment, a second metal diffusion suppressing layer 20 is formed along the grooves T separating the gates MG in the Y direction may be further included. Additionally, the second embodiment can include a third metal diffusion suppressing layer 30 formed along the element separation grooves 10 separating the stacking structures 2 to 6 in the X direction.

As illustrated in FIG. 13A, with respect to the stacking structures 3 to 8 of the gates MG, the grooves T are formed on the side surfaces thereof in the X direction (i.e., the depth direction of the printed surface). The plurality of gates MG are separated from each other in the Y direction. The second metal diffusion suppressing layers 20 are formed along the grooves T on the side surfaces of the stacking structures 3 to 8 of the gates MG. The second metal diffusion suppressing layers 20 can be formed with silicon nitride films, to which, boron (B) or carbon (C), for example, may be added so that the metal diffusion suppressing function is obtained.

Since the second metal diffusion suppressing layers 20 are formed along the side surfaces of the second electric charge storage layers 5 in the Y direction, the diffusion of metal contained in the second electric charge storage layers 5 in may be suppressed the Y direction (outward-diffusion). In addition, since the second metal diffusion suppressing layers 20 are formed along the side surfaces of the first electric charge storage layers 3 in the Y direction, the withstand voltage of the first electric charge storage layer 3 may be enhanced.

As illustrated in FIG. 13B, the third metal diffusion suppressing layers 30 are formed along the element separation grooves 10 on the side surfaces of the stacking structures 2 to 6. The third metal diffusion suppressing layers 30 can be formed by a film of the same material as the second metal diffusion suppressing layers 20. The third metal suppressing layer can be formed with a silicon nitride film to which, boron (B) or carbon (C), for example, may be added. The element separation films 11 and the film 6a are stacked in between the third metal diffusion suppressing layers 30 in the element separation grooves 10.

Since the third metal diffusion suppressing layers 30 are formed on the side surfaces of the second electric charge storage layer 5, the outward-diffusion of the metal contained in the second electric charge storage layer 5 in the X direction may be suppressed. In addition, since the third metal diffusion suppressing layers 30 are formed along the side surfaces of the first electric charge storage layer 3, the withstand voltage of the first electric charge storage layer 3 may be enhanced.

As illustrated in FIG. 13C (plan view taken along line A-A of FIG. 13A and line A-A of FIG. 13B), the second and third metal diffusion suppressing layers 20 and 30 are formed on all of the side surfaces of the second electric charge storage layer 5 to suppress the outward-diffusion from all the side surfaces of the second electric charge storage layer 5. Alternatively, in some embodiments, the second or third metal diffusion suppressing layer 20 or 30 may only be formed on portions of the side surfaces of the second electric charge storage layer 5.

According to the present embodiment, the second metal diffusion suppressing layers 20 are continuously formed on the side surfaces of the first and second electric charge storage layers 3 and 5. However, the configuration is not limited thereto, and the second metal diffusion suppressing layers 20 may be selectively formed only on the side surfaces of the second electric charge storage layer 5.

The third metal diffusion suppressing layers 30 are also formed in the same manner. That is, the third metal diffusion suppressing layers 30 are continuously formed on the side surfaces of the first and second electric charge storage layers 3 and 5. However, the configuration is not limited thereto, the third metal diffusion suppressing layers 30 may be selectively formed only on the side surfaces of the second electric charge storage layer 5 in the Y direction.

A manufacturing method of the second embodiment is described below. In the description below, although general portions are described, other operations may be added between the respective operations, and some of the following operations may be removed, if necessary. In addition, if it is practically possible, the operations may be appropriately replaced.

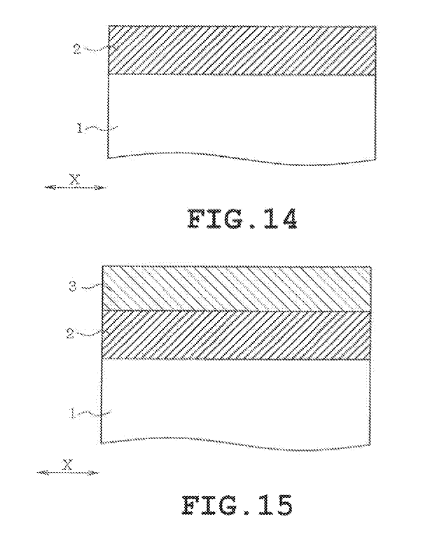

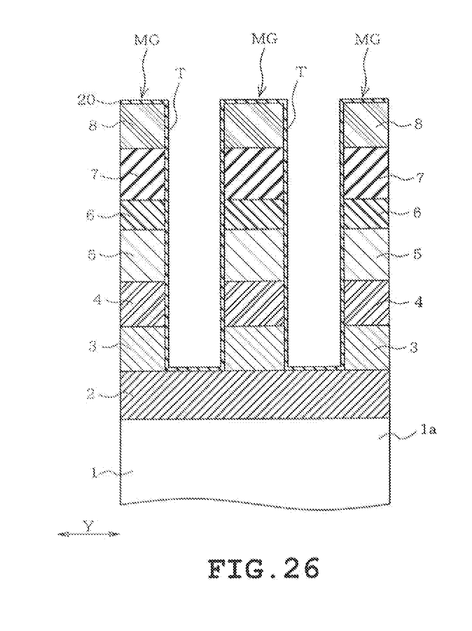

FIGS. 14 to 25 are diagrams illustrating a manufacturing step of a structure corresponding to FIG. 13B. FIG. 26 is a cross-sectional view schematically illustrating a manufacturing step of forming the structure shown in FIG. 13A. The manufacturing steps illustrated in FIGS. 14 to 19 are briefly described since the manufacturing steps are the same steps used for the first embodiment.

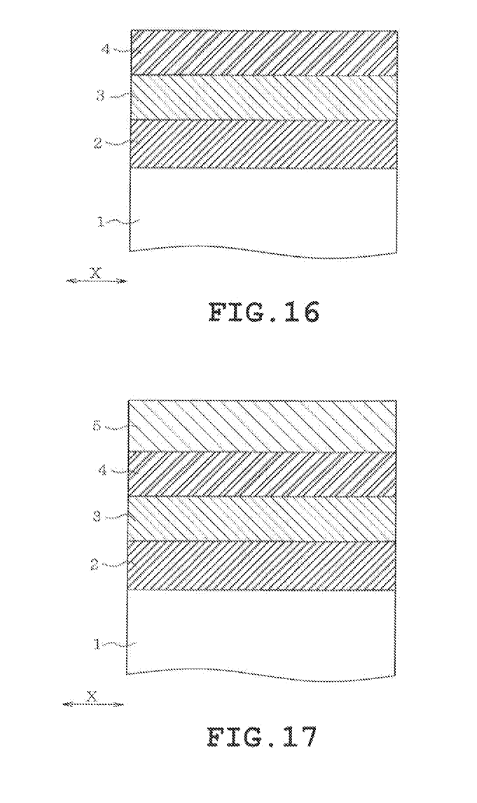

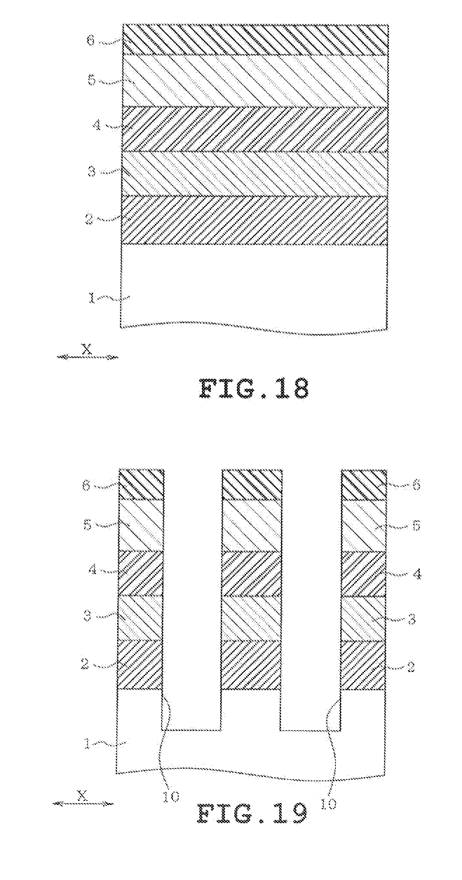

First, as illustrated in FIG. 14, the tunnel insulating film 2 is formed on the semiconductor substrate 1. As illustrated in FIG. 15, the first electric charge storage layer 3 is formed on the tunnel insulating film 2. As illustrated in FIG. 16, the first insulating layer 4 is formed on the first electric charge storage layer 3. As illustrated in FIG. 17, the second electric charge storage layer 5 is formed on the first insulating layer 4. As illustrated in FIG. 18, the first metal diffusion suppressing layer 6 is formed on the second electric charge storage layer 5.

A resist mask (not illustrated) is formed on the first metal diffusion suppressing layer 6 by a lithography method. The formed resist mask is used as a mask, and the element separation grooves 10 are formed on the first metal diffusion suppressing layer 6, the second electric charge storage layer 5, the first insulating layer 4, the first electric charge storage layer 3, the tunnel insulating film 2, and the surface layer of the semiconductor substrate 1, as illustrated in FIG. 19. The element separation grooves 10 are formed to extend in the depth direction (Y direction) of the printed surface.

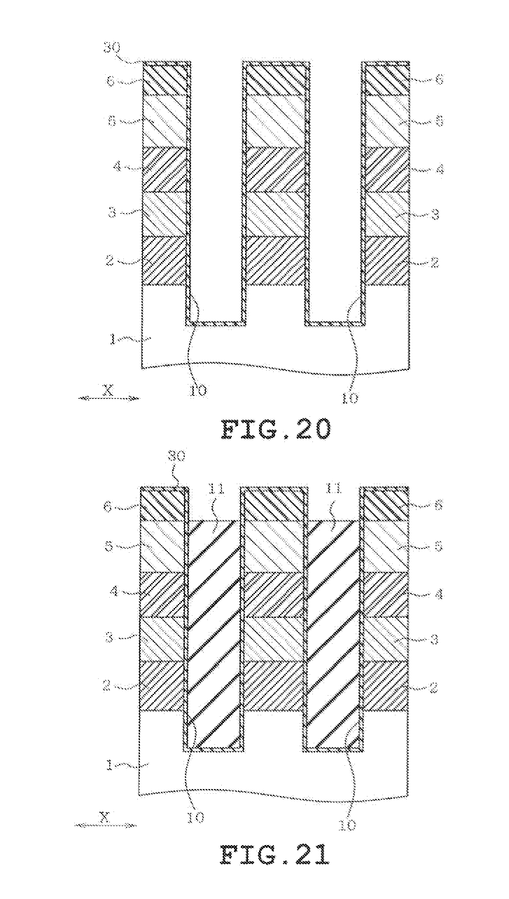

As illustrated in FIG. 20, the third metal diffusion suppressing layers 30 are formed on the entire surfaces of the element separation grooves 10. The third metal diffusion suppressing layers 30 are formed with, for example, a silicon nitride film, by using a CVD method or an ALD method.

As illustrated in FIG. 21, the element separation films are embedded in between the third metal diffusion suppressing layers 30 in the element separation grooves 11. When the element separation films 11 are formed with, for example, a silicon oxide film, the element separation films 11 can be formed by using a CVD method and/or a coating method, or the like. The element separation films 11 are formed in between the third metal diffusion suppressing layers 30 by generally forming the element separation film 11 to the upper surface of the first metal diffusion suppressing layer 6, and then performing an etching so that the height of the upper surface of the element separation film 11 in the element separation grooves 10 becomes the same height of the upper surface of the second electric charge storage layer 5. Since the third metal diffusion suppressing layers 30 are formed along the element separation grooves 10 on the side surfaces of the second electric charge storage layer 5, the outward-diffusion of the metal to the side surfaces of the second electric charge storage layer 5 may be suppressed.

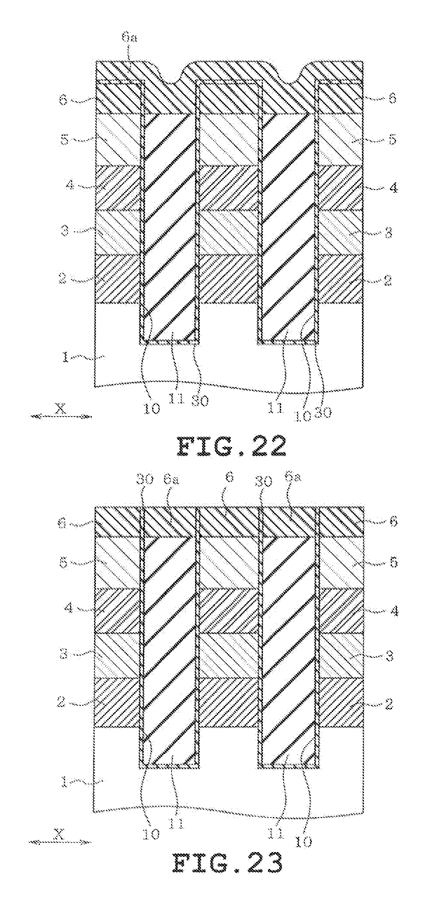

As illustrated in FIG. 22, the film 6a having the same material as the material of the first metal diffusion suppressing layer 6, is formed along the upper surface of the third metal diffusion suppressing layers 30 and the upper surface of the element separation film 11. In some embodiments, the material of the film 6a may be different from the material of the first metal diffusion suppressing layer 6.

As illustrated in FIG. 23, the heights of the upper surfaces of the first metal diffusion suppressing layer 6 and the film 6a are set to be substantially the same by performing the process of flattening the film 6a by a CMP method or performing the etchback process by a RIE method according to the anisotropic conditions.

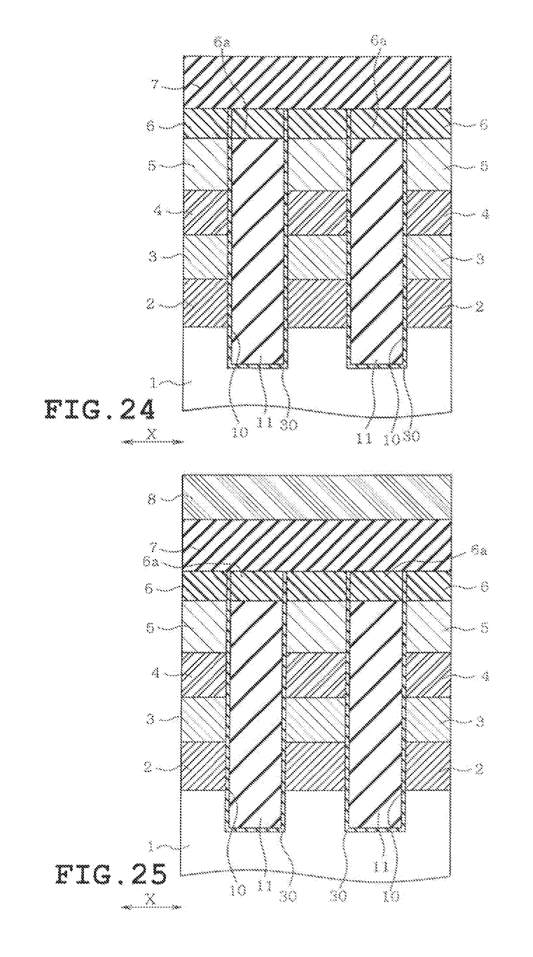

As illustrated in FIG. 24, the second insulating layer 7 is formed on the film 6a and the first metal diffusion suppressing layer 6, and as illustrated in FIG. 25, the control electrode 8 is formed on the second insulating layer 7. When the second insulating layer 7 is formed with, for example, a stacked layer film of a high-permittivity insulating film and a silicon oxide film, then the second insulating layer 7 can be formed by using, for example, an ALD method, a CVD method, or the like. When the control electrode 8 is formed with, for example, polysilicon, the control electrode 8 can be formed by using a CVD method.

A resist mask (not illustrated) is patterned on the control electrode 8, and the patterned resist mask is used as a mask to form grooves T on the stacking structures 3 to 8 as illustrated in FIG. 26. The grooves T are formed to extend along the depth direction (X direction) of the printed surface, and the grooves T segment the stacking structures 3 to 8 by penetrating the control electrode 8, the second insulating layer 7, the first metal diffusion suppressing layer 6, the second electric charge storage layer 5, the first insulating layer 4, and the first electric charge storage layer 3. According to this, the gates MG may be formed. Furthermore, in some embodiments, the grooves T may be formed to be segment the tunnel insulating film 2 in the Y direction.

Subsequently, the second metal diffusion suppressing layers 20 are formed along exposed surfaces of the grooves T. The second metal diffusion suppressing layers 20 are formed with a silicon nitride film to which, for example, boron (B) or carbon (C) is added, by using a CVD method or an ALD method.

Next, dopants are added to the surface layer of the semiconductor substrate 1 by an ion implantation method. The dopants are formed for the source or drain areas 1b (See FIG. 2A, 13A showing areas 1b) according to the following heat process. The interlayer insulating film 9 is formed on the stacking structures 2 to 8, 10, 20, and 30 on the semiconductor substrate 1. When the interlayer insulating film 9 is formed with, for example, a silicon oxide film, the interlayer insulating film 9 can be formed by a CVD method (plasma CVD method and the like) and the like. Thereafter, bit line contacts, source line contacts, via plug, source lines, bit lines, wire line layers using other structures, and the like are formed, the detailed descriptions of which are not provided.

The second embodiment provides many of the same advantages as the first embodiment.

### Other Embodiments

The first to third metal diffusion suppressing layers 10, 20, and 30 are respectively formed with silicon nitride films, and boron (B) atoms may or may not be included in the silicon nitride films. Carbon (C) atoms may also possibly be included in the first to third metal diffusion suppressing layers 10, 20, and 30. The boron (B) and/or carbon (C) may be added to the first to third metal diffusion suppressing layers 10, 20, and 30 when the layers 10, 20, 30 are respectively formed and processed, or after the formation of the respective layers 10, 20, and 30. The boron (B) or carbon (C) atoms may or may not be included in the metal diffusion suppressing layers 10, 20, 30.

The second metal diffusion suppressing layers 20 and the third metal diffusion suppressing layers 30 may be integrated or separate. Although the cell is described with respect to the embodiment including the memory cells MT, when a dummy cell is provided between the selection transistor STS and the memory cells MT on the end portion of the cell string, the embodiment may be applied to the dummy cell as well.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

1. A non-volatile semiconductor memory device comprising:
a semiconductor substrate;
a tunnel insulating film on the semiconductor substrate;
a first electric charge storage layer on the tunnel insulating film;
a first insulating layer on the first electric charge storage layer;
a second electric charge storage layer on the first insulating layer and including a metal containing layer;
a first metal diffusion suppressing layer on the second electric charge storage layer;
a second insulating layer on the first metal diffusion suppressing layer; and
a control electrode on the second insulating layer.

2. The device according to claim 1, further comprising:
a second metal diffusion suppressing layer on a side surface of the second electric charge storage layer.

3. The device according to claim 2,
wherein the second metal diffusion suppressing layer extends to cover a side surface of the first electric charge storage layer.

4. The device according to claim 1, wherein the metal containing layer is a metal layer.

5. The device according to claim 1,
wherein the second insulating layer includes a portion to trap charges.

6. The device according to claim 1, further comprising:
multiple rows of cells that include the first and second electric charge storage layers, the rows extending in a first direction and parallel to each other and spaced apart in a second direction intersecting the first direction; and
second metal diffusion suppressing layers on side surfaces of the second electric charge storage layers of the cells.

7. The device according to claim 6,
wherein second metal diffusion suppressing layer extends to cover side surfaces of the first electric charge storage layers of the cells.

8. The device according to claim 1, further comprising:
an element separation film adjacent to the second electric charge storage layer in a first direction,
wherein an upper surface of the second electric charge storage layer and an upper surface of the element separation film are flush with each other, and
wherein a film having a same material as the first metal diffusion suppressing layer is disposed on the upper surface of the element separation film.

9. The device according to claim 1, further comprising:
multiple rows of cells that include the first and second electric charge storage layers, the rows extending in a first direction and parallel to each other and spaced apart in a second direction intersecting the first direction;
second metal diffusion suppressing layers on side surfaces of the second electric charge storage layers of the cells in the first direction; and
third metal diffusion suppressing layers on side surfaces of the second electric charge storage layers of the cells in the second direction,
wherein all of the side surfaces of the second electric charge storage layer are covered with the second metal diffusion suppressing layers and the third metal diffusion suppressing layers.

10. A non-volatile semiconductor memory device comprising:
a semiconductor substrate;
a tunnel insulating film on the semiconductor substrate;
a first electric charge storage layer on the tunnel insulating film;
a first insulating layer on the first electric charge storage layer;
a second electric charge storage layer on the first insulating layer and including a metal containing layer;
a first silicon nitride film on the second electric charge storage layer;
a second insulating layer on the first silicon nitride film; and
a control electrode on the second insulating layer.

11. The device according to claim 10, wherein the metal containing layer is a metal layer.

12. The device according to claim 10,
wherein the first silicon nitride film contains boron (B) atoms or carbon (C) atoms.

13. The device according to claim 10, further comprising:
a second silicon nitride film formed on a side surface of the second electric charge storage layer.

14. The device according to claim 13,
wherein the second silicon nitride film contains boron (B) atoms or carbon (C) atoms.

15. The device according to claim 13, further comprising:
multiple rows of cells that include the first and second electric charge storage layers, the rows extending in a first direction and are parallel to each other and spaced apart in a second direction intersecting the first direction; and
third silicon nitride films on side surfaces of the second electric charge storage layer of the cells.

16. The device according to claim 15,
wherein the third silicon nitride film contains boron (B) atoms or carbon (C) atoms.

17. The device according to claim 15, further comprising:
an element separation film adjacent to the second electric charge storage layer in the first direction,
wherein an upper surface of the second electric charge storage layer and an upper surface of the element separation film are flush with each other, and
wherein a fourth silicon nitride film is disposed on an upper surface of the element separation film.

18. The device according to claim 10,
wherein the second electric charge storage layer contains ruthenium (Ru).

19. The device according to claim 10,
wherein the second electric charge storage layer contains any one of tungsten silicide (WSi), tungsten (W), chromium (Cr), and copper (Cu).

20. The device according to claim 10, further comprising:
multiple rows of cells that include the first and second electric charge storage layers, the rows extending in a first direction and parallel to each other and spaced apart in a second direction intersecting the first direction;
second silicon nitride films on side surfaces of the second electric charge storage layer of the cells in the first direction; and
third silicon nitride film on side surfaces of the second electric charge storage layer of the cells in the second direction,
wherein all of the side surfaces of the second electric charge storage layer are covered with the second metal diffusion suppressing layers and the third metal diffusion suppressing layers.
